(19) United States
(12) Patent Application Publication
(10) Pub. No.: US 2008/0225597 A1
(43) Pub. Date: Sep. 18, 2008

(54) METHOD OF DETECTING AN UNDER PROGRAM CELL IN A NON-VOLATILE MEMORY DEVICE AND METHOD OF PROGRAMMING THE UNDER PROGRAM CELL USING THE SAME

(75) Inventor: Jin Su Park, Daegu (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/771,513

(22) Filed: Jun. 29, 2007

(30) Foreign Application Priority Data
Mar. 14, 2007 (KR) 2007-25098

(51) Int. Cl. G11C 29/00; G11C 11/34; G11C 8/08

(52) U.S. Cl. 365/185.22; 365/185.25

(57) ABSTRACT

A method of detecting an under program cell includes detecting second memory cells of programmed first memory cells. A threshold voltage of the second memory cell is higher than a first verifying voltage. A third memory cell is detected in the second memory cells. A threshold voltage of the third memory cell is smaller than a second verifying voltage. A method of programming a cell in a non-volatile memory device includes performing an program operation on selected memory cells. First memory cells are detected in the memory cells on which the program operation is performed. A threshold voltage of the first memory cell is higher than a first verifying voltage. An under program cell is detected in the first memory cells. A threshold voltage of the under program cell is smaller than a second verifying voltage. The under program cell is then programmed.

### CROSS-REFERENCE TO RELATED APPLICATIONS

This application claims priority to Korean Patent Application No. 2007-25098, filed on Mar. 14, 2007, the contents of which are incorporated herein by reference in its entirety.

### BACKGROUND OF THE INVENTION

The present invention relates to a method of detecting an under program cell in a non-volatile memory device and a method of programming a cell using the same.

Recently, the demand has increased for a non-volatile memory device which electrically programs and erases data and does not require a refresh function that periodically rewrites data.

The non-volatile memory device generally includes a memory cell array where memory cells for storing data are arranged in a matrix, and a page buffer for programming data to a specific memory cell of the memory cell array and reading data from the memory cell.

A voltage level of a bit line connected to a cell string having a certain number of memory cells is measured so as to determine whether or not a specific memory cell included in the memory cell array is programmed.

To determine accurately whether or not a specific cell is programmed, a sufficient read margin is required. Specifically, since each of the memory cells programmed by a multi level cell (MLC) program method has various threshold voltage distributions compared to that programmed by a single level cell (SLC) program method, a sufficient sensing margin is required between the threshold voltage distributions.

Although a program objection cell is not programmed using a voltage greater than a verifying reference voltage, it may be verified that the cell is programmed by a bouncing phenomenon of a source line generated in accordance with a characteristic of the memory cell array. In other words, an under program cell is generated. As a result, the sensing margin is decreased due to the under program cell.

### SUMMARY OF THE INVENTION

It is a feature of the present invention to provide a method of detecting an under program cell.

It is another feature of the present invention to provide a method of programming a cell in a non-volatile memory device using the method of detecting the under program cell.

A method of detecting an under program cell according to one example embodiment of the present invention includes detecting second memory cells in programmed first memory cells, wherein a threshold voltage of the second memory cell is higher than a first verifying voltage, and detecting a third memory cell in the second memory cells, wherein a threshold voltage of the third memory cell is smaller than a second verifying voltage.

A method of programming a cell in a non-volatile memory device according to one example embodiment of the present invention includes: performing a program operation on selected memory cells; detecting first memory cells of the programmed memory cells, wherein a threshold voltage of the first memory cell is higher than a first verifying voltage; detecting an under program cell of the first memory cells, wherein a threshold voltage of the under program cell is smaller than a second verifying voltage; and programming the under program cell.

As described above, a method of the present invention detects an under program cell. In addition, since an extra program operation is performed on the under program cell, the under program cell is removed. As a result, a sensing margin is increased.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a view illustrating a common memory cell array in a non-volatile memory device;

FIG. 2A and FIG. 2B are views illustrating a source line bouncing phenomenon generated by a resistance of a source line;

FIG. 3 is a view illustrating a graph showing a read margin of under program cells;

FIG. 4 is a view illustrating circuitry of a page buffer employing a method of programming an under program cell according to one example embodiment of the present invention;

FIG. 5 is a flow chart illustrating a process of programming the under program cell according to one example embodiment of the present invention;

FIG. 6 is a timing diagram illustrating a waveform related to voltage signals that are provided when a read operation is performed in order to detect the under program cell according to one example embodiment of the present invention; and

FIG. 7 is a timing diagram illustrating waveforms related to signals that are provided in a read operation in order to detect the under program cell according to another example embodiment of the present invention.

### DESCRIPTION OF SPECIFIC EMBODIMENTS

Hereinafter, the preferred embodiments of the present invention will be explained in detail with reference to the accompanying drawings.

FIG. 1 is a view illustrating a common memory cell array in a non-volatile memory device.

The memory cell array includes memory cells for storing data, word lines WL0 to WLn for selectively activating the memory cells and bit lines BL0 to BLm for inputting data to the memory cell or outputting data from the memory cell. The word lines WL0 to WLn and the bit lines BL0 to BLm are arranged in a matrix.

In addition, the memory cell array includes a plurality of cell strings having memory cells coupled in series between a source select line SSL and a drain select line DSL.

Gates of the memory cells are coupled to the word lines WL0 to WLn. A group of memory cells coupled to the same word line is referred to as a page.

Additionally, the memory cell array includes a block where the cell strings coupled to each of the bit lines BL0 to BLm are coupled in parallel to a common source line.

Each of the cell strings is coupled to the common source line.

Each of the source lines is coupled to a metal bypass line coupled in parallel to a corresponding bit line. The source line is an n+ diffused source line, and has a high resistance. As a result, noise occurs due to a high resistance of the source line, which affects control of a threshold voltage.

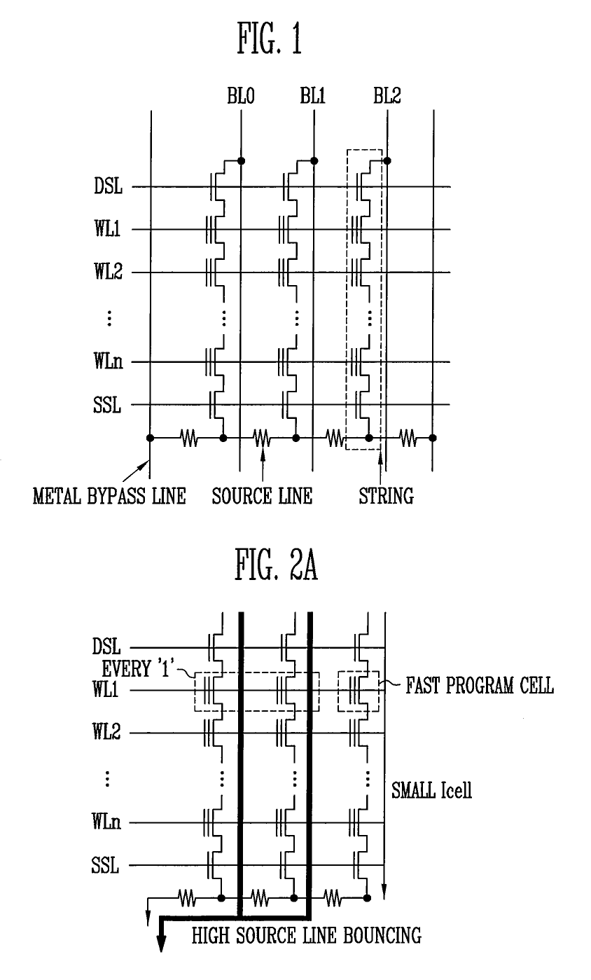

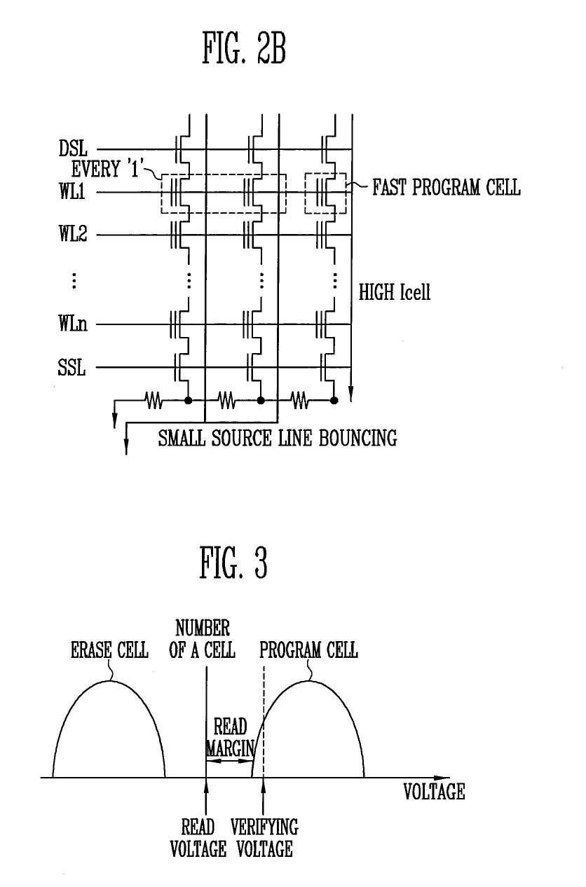

FIG. 2A and FIG. 2B are views illustrating a source line bouncing phenomenon generated by a resistance of the source line. In the following description, it is assumed that every page of a selected word line is programmed.

FIG. 2A shows an initially programmed cell, i.e. fast program cell, and a slow program cell which is a program objection cell that is not programmed. The fast program cell and the slow program cell are coupled to the same word line.

Since the slow program cell (referred to as “1”) is not yet programmed, the slow program cell is discharged to a ground voltage from a precharge level. The voltage of the source line is increased by the resistance of the source line, and a source voltage of the fast program cell is augmented. As a result, a sensing current Icell of the fast program cell is decreased due to the noise of the common source line.

Although the threshold voltage of the fast program cell is smaller than a verifying voltage, verification of the fast program cell is missed due to the decreased current Icell. Accordingly, the fast program cell is regarded as programmed. As a result, the fast program cell is not programmed.

FIG. 2B illustrates that the noise of the common source line is reduced as the slow program cells are programmed. Since the noise of the common source line is decreased, the current Icell through the fast program cell is increased.

In brief, a bouncing phenomenon occurs as the voltage level of the source line is varied in accordance with a program state of a peripheral cell. As a result, a level of a current through a certain cell is changed. Thus, a cell that is not programmed is regarded as being programmed. In other words, an under program cell is generated.

FIG. 3 is a view illustrating a graph showing a read margin of under program cells.

Generally, when a threshold voltage of a program cell is greater than a certain verifying voltage, the program cell is regarded as programmed. In addition, a read voltage is applied in a process of reading data stored in a specific cell after a program operation is performed. The read voltage is smaller than the verifying voltage by a certain level.

The read margin refers to the difference between the verifying voltage and the read voltage. Data stored in a given cell may be more accurately read when the read margin is sufficiently ensured.

However, when the under program cell is generated due to, for example, the above-described bouncing phenomenon, the read margin is reduced.

To address the problem, the method of the present embodiment detects the under program cell, and performs a subsequent program operation on the detected under program cell so that a threshold voltage of the under program cell is increased to a voltage greater than the verifying voltage. In other words, the present invention provides the program method of increasing the read margin by subsequently programming the under program cell.

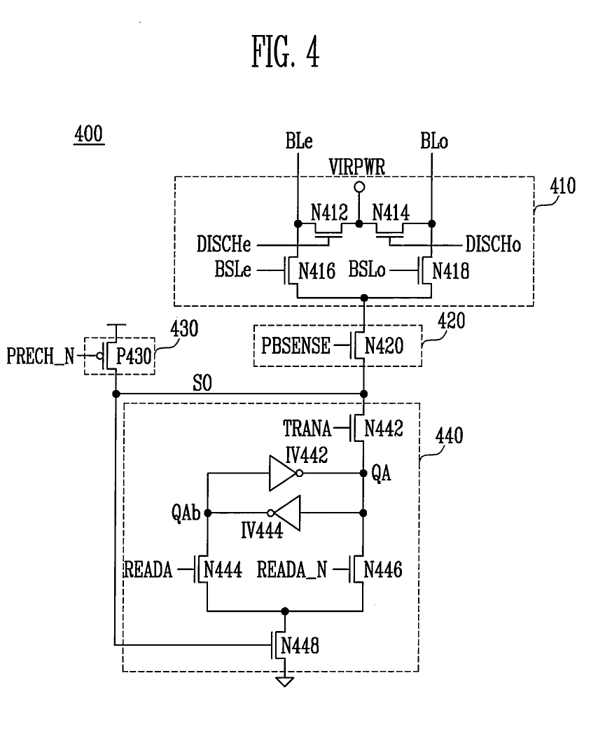

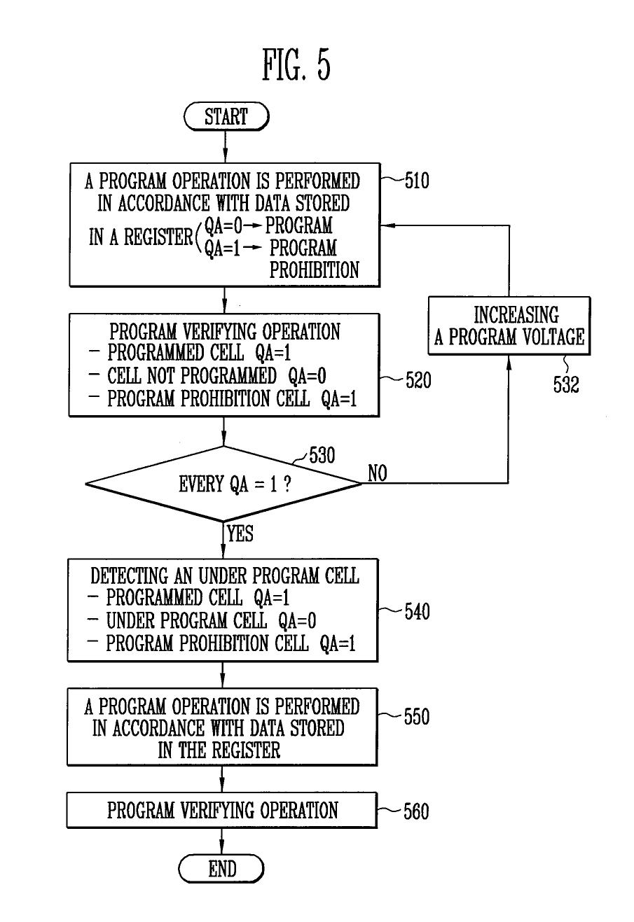

FIG. 4 is a view illustrating circuitry of a page buffer employing a method of programming the under program cell according to one example embodiment of the present invention.

In FIG. 4, the page buffer 400 includes a bit line selecting circuit 410, a bit line sensing circuit 420, a sensing node precharge circuit 430 and a register 440.

The bit line selecting circuit 410 has an N-MOS transistor N416 for coupling an even bit line BLe to the bit line sensing circuit 420 in response to a first bit line selecting signal BSLe, and an N-MOS transistor N418 for coupling an odd bit line BLo to the bit line sensing circuit 420 in response to a second bit line selecting signal BSLo. Hence, the bit line BLe or BLo is selectively coupled to the bit line sensing circuit 420 in accordance with a voltage level of a corresponding bit line selecting signal BSLe or BSLo.

In addition, the bit line selecting circuit 410 includes an N-MOS transistor N412 for coupling the even bit line BLe to a control signal inputting terminal in response to a first discharge signal DISCHe, and an N-MOS transistor N414 for coupling the odd bit line BLo to the control signal inputting terminal in response to a second discharge signal DISCHo. A control signal VIRPWR having a certain level is provided to the control signal inputting terminal. Therefore, the bit line BLe or BLo is precharged to a high level or discharged to a low level in accordance with the voltage level of the control signal VIRPWR.

The bit line sensing circuit 420 couples the bit line BLe or BLo to a sensing node SO in response to a bit line sensing signal PBSENSE at a high level, measures the voltage level of the bit line BLe or BLo, and applies a voltage level of data stored in a specific cell to the sensing node SO in accordance with the measured voltage level. The sensing signal PBSENSE has a first voltage V1 or a second voltage V2 that is smaller than the first voltage V1.

In one example embodiment of the present invention, the page buffer 400 may not include the bit line sensing circuit 420, but may directly couple the bit line selecting circuit 410 to the sensing node SO. The page buffer 400 may perform an operation similar to the operation described above. In other words, the bit line selecting signal BSLe or BSLo having the first voltage V1 or the second voltage V2 is applied to the corresponding N-MOS transistor N416 or N418. Thus, the voltage level of the bit line BLe or BLo is measured so that the voltage level of data stored in the specific cell is applied to the sensing node SO.

The sensing node precharge circuit 430 couples the sensing node SO to a power supply voltage, thereby precharging the sensing node SO to a high level voltage.

Further, the sensing node precharge circuit 430 includes a P-MOS transistor P430 for coupling the sensing node SO to the power supply voltage in response to a precharge signal PRECH_N having a low level.

The register 440 includes a latch having two inverters IV442 and IV444, an N-MOS transistor N448 which is activated in response to the voltage level of the sensing node SO and provides the power supply voltage to the latch, an N-MOS transistor N446 which is coupled between a first node QA and the N-MOS transistor N448 and is activated in response to a first read signal READA_N, and an N-MOS transistor N444 which is coupled between a second node QAb and the N-MOS transistor N448 and is activated in response to a second read signal READA.

Hereinafter, a process of programming the under program cell by using the page buffer 400 according to one example embodiment of the present invention will be described in detail.

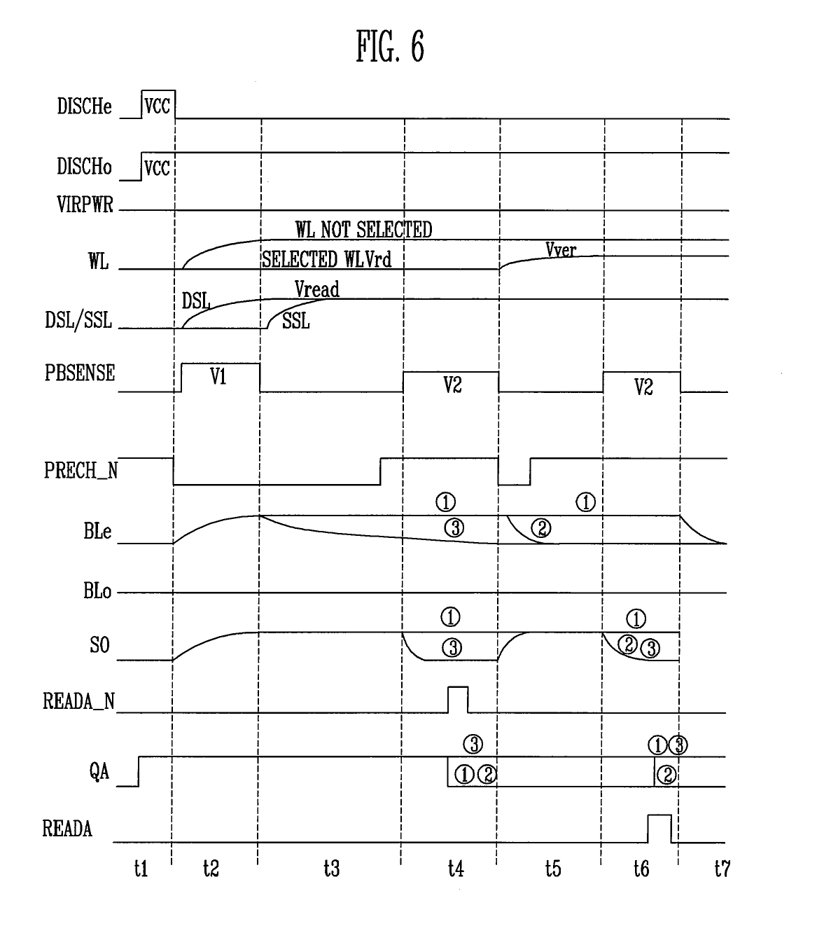

FIG. 5 is a flow chart illustrating a process of programming the under program cell according to one example embodiment of the present invention.

In step S510, a program operation is performed in accordance with data stored in the register 440 of the page buffer 400.

The execution of the program operation depends on data stored in the first node QA of the latch included in the register 440.

When data ‘0’ at a low level is stored in the first node QA, a first cell corresponding to the data ‘0’ is regarded as a program objection cell. Thus, the program operation is performed on the first cell. However, when data ‘1’ at a high level is stored in the first node QA, a second cell corresponding to the data ‘1’ is considered a program prohibition cell. Thus, the second cell is not programmed.

The above program operation is the same as a conventional program operation in a non-volatile memory device. Thus, any further description of the conventional program operation is omitted.

In step S520, a program verifying operation is performed to verify whether or not the cell was effectively programmed by the program operation.

The program verifying operation uses the fact that the voltage level of the sensing node SO is varied in accordance with the program of a given cell. The voltage level of the sensing node SO maintains a high level when the cell is programmed, but has a low level when the cell is not programmed.

The activation of the transistor N448 included in the register 440 depends on the voltage level of the sensing node SO. The second read signal READA is provided to the N-MOS transistor N444 at a high level.

Since the voltage level of the sensing node SO is at a high level when the cell is programmed, the N-MOS transistor N448 is activated. Moreover, since the N-MOS transistor N444 is activated in accordance with the second read signal READA, data at a high level is stored in the first node QA. In other words, the data stored in the first node QA at a low level in step S510 is changed to data at a high level.

However, when a cell is not programmed even though the cell is a program objection cell (i.e., when the data at a low level is stored in the first node QA in step S510), the voltage level of the sensing node SO is at a low level. Accordingly, the N-MOS transistor N448 is not activated. Thus, the data stored in the first node QA is maintained at a low level.

When a cell is a program prohibition cell (i.e., when the data at a high level is stored in the first node QA in step S510), the cell is not programmed. Accordingly, the voltage level of the sensing node SO is at a low level. Thus, the N-MOS transistor N448 is not activated. As a result, the data stored in the first node QA is maintained at a high level.

In brief, when a cell is programmed in accordance with the program verifying operation, the data at a high level is stored in the first node QA. In addition, when a cell is a program prohibition cell, the data at a high level is stored in the first node QA. However, when a cell is a program objection cell but is not programmed, the data at a low level is stored in the first node QA.

In step S530, when all of the data is stored in the first node QA at a high level, the program operation and the program verifying operation are complete. However, when certain data is stored in the first node QA at a low level, the program operation is performed again.

In step S532, a program voltage is applied at an increased level in accordance with an incremental step pulse programming (hereinafter, referred to as “ISPP”) method.

In step S540, when the program verifying operation is finished, a process of detecting an under program cell is performed.

The process of detecting the under program cell includes separating a program prohibition cell from first cells of which a threshold voltage is higher than a read reference voltage, and detecting a second cell of the first cells. A threshold voltage of the second cell is smaller than a verifying reference voltage.

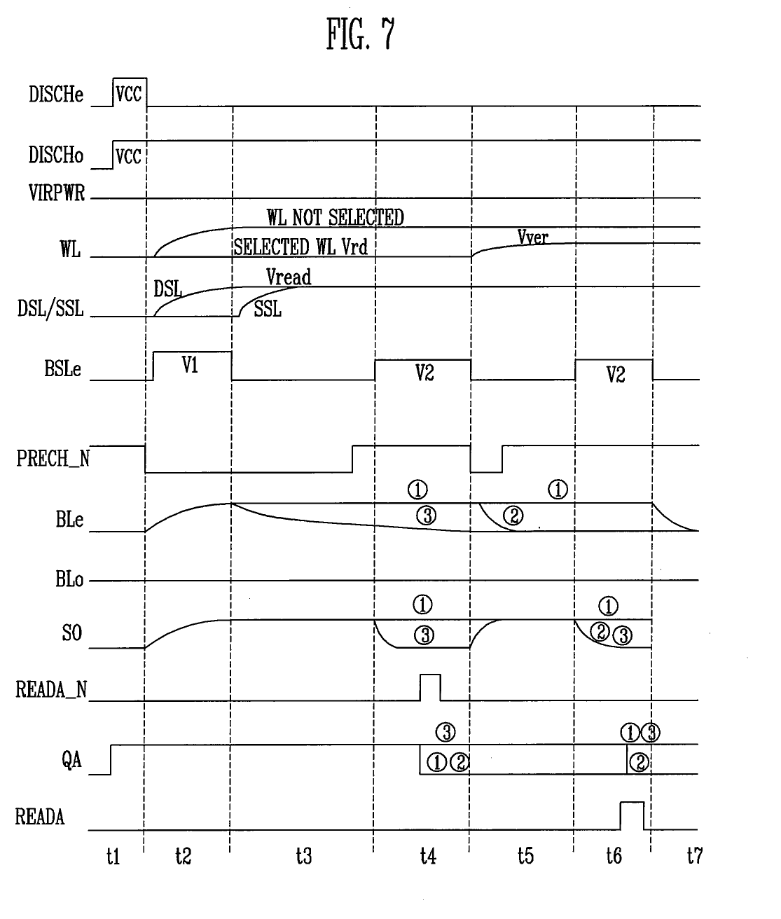

FIG. 6 is a timing diagram illustrating a waveform related to voltage signals provided when a read operation is performed in order to detect the under program cell according to one example embodiment of the present invention.

(1) T1 Interval

A bit line is discharged before a cell string having a specific cell to be read is coupled to the bit line.

Subsequently, the even discharge signal DISCHe is enabled for a given time period. Thus, the N-MOS transistor N412 is activated. Since the bias voltage VIRPWR is at a low level, the even bit line BLe is discharged to a low level voltage.

In addition, the odd discharge signal DISCHo is enabled. Thus, the N-MOS transistor N414 is activated. As a result, the odd bit line BLo is discharged to a low level voltage.

(2) T2 Interval

A voltage Vread having a high level is applied to a drain select line DSL. Thus, the cell string having the cell to be read is coupled to a corresponding bit line.

The voltage Vread at a high level is applied to a source select line SSL. Thus, a cell string having a specific cell of a memory cell array is coupled to the common source line. As a result, a current path is formed between a corresponding bit line and the common source line. In FIG. 6, the voltage Vread is applied during the T3 interval, but may be applied during the T2 interval.

The read reference voltage Vrd is applied to a word line related to a selected cell, and the voltage Vread at a high level is provided to a word line related to a cell that is not selected.

In FIG. 6, the read reference voltage is 0V However, since various read reference voltages exist in an MLC program method, a read reference voltage corresponding to a certain word line is applied.

Next, a bit line coupled to the specific cell is precharged to a high level.

The sensing node SO is precharged to a level of the power supply voltage through the sensing node precharge circuit 430 of the page buffer 400. Additionally, the bit line sensing signal PBSENSE having the first voltage V1 is provided to the bit line sensing transistor N420 of the bit line sensing circuit 420. Thus, the sensing node SO precharged to a high level is coupled to a corresponding bit line.

The coupling of the bit line BLe or BLo and the sensing node SO depends on the bit line selecting signal BSLe or BSLo. For example, when the even bit line BLe is coupled to the sensing node SO, the even bit line selecting signal BSLe is provided at a high level. As a result, the bit line BLe or BLo is precharged to a certain voltage level (V1−Vt).

(3) T3 Interval

The voltage Vread is applied at a high level to the source select line SSL. Thus, a cell string having a specific cell of the memory cell array is coupled to the common source line. As a result, a current path is formed between a corresponding bit line and the common source line. As mentioned above, the voltage Vread is applied during the T3 interval, but the voltage Vread may be provided during the T2 interval.

Subsequently, a program of a specific cell to be read is measured in accordance with the voltage level of a corresponding bit line.

To measure the program of the specific cell, the level of the bit line selecting signal BSLe or BSLo is converted from a high level to a low level. Thus, a corresponding bit line is not coupled to the sensing node SO during a given time period. In the given time period, the voltage level of the bit line coupled to the cell is changed in accordance with the program of the specific cell.

Accordingly, when the specific cell is programmed, the voltage level of a corresponding bit line is maintained at a high level. However, when a certain cell is not programmed, the voltage level of a corresponding bit line is decreased to a low level.

Subsequently, the level of the precharge signal PRECH_N is converted from a low level to a high level before the T4 interval. Thus, the sensing node SO and the power supply voltage are uncoupled.

(4) T4 Interval

Data stored in the specific cell is sensed in accordance with the voltage level of the bit line BLe or BLo. The sensed data is then stored in the register 440.

To sense the data stored in the specific cell, the bit line sensing signal PBSENSE at a low level is converted to the second voltage V2 that is smaller than the first voltage V1. Thus, a corresponding bit line is coupled to the sensing node SO for a given time period. Accordingly, the transistor N420 is activated or deactivated in accordance with the voltage level of the bit line. In other words, when the voltage level of the bit line is smaller than the voltage difference (V2−Vt), the transistor N420 is activated. As a result, the bit line is coupled to the sensing node SO. Thus, charges are shared between the bit line and the sensing node SO. Hence, the voltage level of the sensing node SO is lowered.

However, when the voltage level of the bit line is higher than the voltage difference (V2−Vt), the transistor N420 is deactivated. As a result, the bit line is not coupled to the sensing node SO. Thus, the voltage level of the sensing node SO is maintained. Accordingly, the voltage level of the sensing node SO depends on the voltage level of the bit line. Since the voltage level of the sensing node SO is maintained at a high level when a corresponding cell is programmed, the transistor N448 of the register 440 is activated.

Since the first read signal READA_N at a high level is provided to the N-MOS transistor N446 of the register 440, data at a low level is stored in the first node QA when the cell is programmed. Since the under program cell is programmed to a voltage greater than the read reference voltage, data at a low level is stored in the first node QA like the programmed cell.

When the cell is erased, data at a high level is stored in the first node QA.

(5) T5 Interval

A step of separating a second cell from first cells is performed. The threshold voltage of the first cell is greater than the read reference voltage, and the threshold voltage of the second cell is less than the verifying reference voltage.

To perform the step of separating a second cell from first cells, the verifying reference voltage higher than the read reference voltage is applied to a word line coupled to a cell to be read, and a high level voltage is provided to the other word lines. In other words, the verifying reference voltage Vver is applied to the selected word line instead of the read reference voltage. This is for detecting the under program cell. The threshold voltage of the under program cell is higher than the read reference voltage, but is smaller than the verifying reference voltage Vver.

The bit line sensing signal PBSENSE is converted from a high level to a low level. Thus, a corresponding bit line is not coupled to the sensing node SO for a certain time period. The voltage level of the bit line coupled to the specific cell is changed depending on the program of the cell.

In other words, when the cell is programmed to a voltage greater than the verifying reference voltage Vver, the voltage level of the bit line is maintained at a high level. However, when the cell is programmed to a voltage less than the verifying reference voltage Vver, the voltage level of the bit line is decreased to a low level.

The precharge signal PRECH_N is converted to a low level in the next interval T6. Thus, the sensing node SO is precharged to a high level.

(6) T6 Interval

Data stored in a specific cell is sensed in accordance with the voltage level of the bit line BLe or BLo. The sensed data is then stored in the register 440.

To sense the data stored in the specific cell, the bit line sensing signal PBSENSE at a low level is converted to the second voltage V2 that is less than the first voltage V1. Thus, a corresponding bit line is coupled to the sensing node SO for a given time period. Accordingly, the transistor N420 is activated or deactivated in accordance with the voltage level of the bit line. In other words, when the voltage level of the bit line is smaller than the voltage difference (V2−Vt), the transistor N420 is activated. As a result, the bit line is coupled to the sensing node SO. Thus, charges are shared between the bit line and the sensing node SO. Hence, the voltage level of the sensing node SO is lowered.

However, when the voltage level of the bit line is higher than the voltage difference (V2−Vt), the transistor N420 is deactivated. As a result, the bit line is not coupled to the sensing node SO. Thus, the voltage level of the sensing node SO is maintained. Accordingly, the voltage level of the sensing node SO depends on the voltage level of the bit line. Since the voltage level of the sensing node SO is maintained at a high level when a corresponding cell is programmed, the transistor N448 of the register 440 is activated.

However, since the threshold voltage of the under program cell or the threshold voltage of the program prohibition cell is smaller than the verifying reference voltage Vver, the voltage level of the sensing node SO is a low level. As a result, the N-MOS transistor N448 of the register 440 remains deactivated.

Since the second read signal READA at a high level is provided to the N-MOS transistor N444 of the register 440, data at a high level is stored in the first node QA when a corresponding cell is programmed.

However, since the threshold voltage of the under program cell is smaller than the verifying reference voltage Vver, the data stored in the T4 interval is maintained at a low level.

In a program prohibition cell, the data stored in the T4 interval is maintained at a high level.

In brief, the data at a low level is stored in the first node QA in the under program cell. However, the data at a high level is stored in the first node QA for the cell programmed normally or the program prohibition cell.

FIG. 7 is a timing diagram illustrating waveforms related to signals provided in a read operation in order to detect the under program cell according to another example embodiment of the present invention. The waveforms in FIG. 7 are similar to those in FIG. 6. The method of the present embodiment is used in a page buffer not having the bit line sensing circuit 420. In the embodiment in FIG. 7, a first voltage V1 or a second voltage V2 is provided to the bit line select transistor N416 or N418 of the bit line selecting circuit 410.

(1) T1 Interval

A bit line is discharged before a cell string having a specific cell to be read is coupled to the bit line.

Subsequently, the even discharge signal DISCHe is enabled for a given time period. Thus, the N-MOS transistor N412 is activated. Since the bias voltage VIRPWR is at a low level, the even bit line BLe is discharged to a low level voltage.

In addition, the odd discharge signal DISCHo is enabled. Thus, the N-MOS transistor N414 is activated. As a result, the odd bit line BLo is discharged to a low level voltage.

(2) T2 Interval

A voltage Vread is applied to the drain select line DSL at a high level. Thus, the cell string having the cell to be read is coupled to a corresponding bit line.

The voltage Vread is applied to the source select line SSL at a high level. Thus, a cell string having a specific cell of a memory cell array is coupled to the common source line. As a result, a current path is formed between a corresponding bit line and the common source line. In FIG. 7, the voltage Vread is applied during the T3 interval, but may be applied during the T2 interval.

The read reference voltage Vrd is applied to a word line related to a selected cell, and the voltage Vread is provided at a high level to a word line related to a cell that is not selected.

In FIG. 7, the read reference voltage is 0V. However, since various read reference voltages exist in an MLC program method, a read reference voltage corresponding to a certain word line is applied.

Next, a bit line coupled to the specific cell is precharged to a high level.

The sensing node SO is precharged to a level of the power supply voltage through the sensing node precharge circuit 430 of the page buffer 400. Additionally, the bit line selecting signal BSLe or BSLo having the first voltage V1 is provided to the bit line selecting transistor N412 or N414 of the bit line selecting circuit 410. Thus, the sensing node SO precharged to a high level is coupled to a corresponding bit line. Accordingly, the bit line BLe or BLo is precharged to a certain voltage level (V1−Vt).

(3) T3 Interval

The voltage Vread is applied to the source select line SSL at a high level. Thus, a cell string having a specific cell of the memory cell array is coupled to the common source line. As a result, a current path is formed between a corresponding bit line and the common source line. As mentioned above, the voltage Vread is applied during the T3 interval, but the voltage Vread may be provided during the T2 interval.

Subsequently, a program of a specific cell to be read is measured in accordance with the voltage level of a corresponding bit line.

To measure the program of the specific cell, the level of the bit line selecting signal BSLe or BSLo is converted from a high level to a low level. Thus, a corresponding bit line is not coupled to the sensing node SO during a given time period. During the given time period, the voltage level of the bit line coupled to the cell is changed in accordance with the program of the specific cell.

Accordingly, when the specific cell is programmed, the voltage level of a corresponding bit line is maintained at a high level. However, when a certain cell is not programmed, the voltage level of a corresponding bit line is decreased to a low level.

Subsequently, the level of the precharge signal PRECH_N is converted from a low level to a high level before the T4 interval. Thus, the sensing node SO and the power supply voltage are uncoupled.

(4) T4 Interval

Data stored in the specific cell is sensed in accordance with the voltage level of the bit line BLe or BLo. The sensed data is then stored in the register 440.

To sense the data stored in the specific cell, the bit line selecting signal BSLe or BSLo at a low level is converted to the second voltage V2 that is smaller than the first voltage V1. Thus, a corresponding bit line is coupled to the sensing node SO for a given time period. Accordingly, the transistor N412 or N414 is activated or deactivated in accordance with the voltage level of the bit line. In other words, when the voltage level of the bit line is smaller than the voltage difference (V2−Vt), the transistor N412 or N414 is activated. As a result, the bit line is coupled to the sensing node SO. Thus, charges are shared between the bit line and the sensing node SO.

Hence, the voltage level of the sensing node SO is lowered.

However, when the voltage level of the bit line is higher than the voltage difference (V2−Vt), the transistor N412 or N414 is deactivated. As a result, the bit line is not coupled to the sensing node SO. Thus, the voltage level of the sensing node SO is maintained. Accordingly, the voltage level of the sensing node SO depends on the voltage level of the bit line. Since the voltage level of the sensing node SO is maintained at a high level when a corresponding cell is programmed, the transistor N448 of the register 440 is activated.

Since the first read signal READA_N at a high level is provided to the N-MOS transistor N446 of the register 440, data at a low level is stored in the first node QA when the cell is programmed. Since the under program cell is programmed to a voltage greater than the read reference voltage, data at a low level is stored in the first node QA like the programmed cell.

However, when the cell is erased, data at a high level is stored in the first node QA.

(5) T5 Interval

A step of separating a second cell from first cells is performed. The threshold voltage of the first cell is greater than the read reference voltage, and the threshold voltage of the second cell is less than the verifying reference voltage.

To perform the step of separating a second cell from first cells, the verifying reference voltage higher than the read reference voltage is applied to a word line coupled to a cell to be read, and a voltage at a high level is provided to the other word lines. In other words, the verifying reference voltage Vver is applied to the selected word line instead of the read reference voltage. This is for detecting the under program cell. The threshold voltage of the under program cell is higher than the read reference voltage, but is smaller than the verifying reference voltage Vver.

The bit line selecting signal BSLe or BSLo is converted from a high level to a low level. Thus, a corresponding bit line is not coupled to the sensing node SO for a certain time period. The voltage level of the bit line coupled to the specific cell is changed depending on the program of the cell.

In other words, when the cell is programmed to a voltage greater than the verifying reference voltage Vver, the voltage level of the bit line is maintained at a high level. However, when the cell is programmed to a voltage less than the verifying reference voltage Vver, the voltage level of the bit line is decreased to a low level.

The precharge signal PRECH_N is converted to a low level in the next interval T6. Thus, the sensing node SO is precharged to a high level.

(6) T6 Interval

Data stored in a specific cell is sensed in accordance with the voltage level of the bit line BLe or BLo. The sensed data is then stored in the register 440.

To sense the data stored in the specific cell, the bit line selecting signal BSLe or BSLo at a low level is converted to the second voltage V2 that is smaller than the first voltage V1. Thus, a corresponding bit line is coupled to the sensing node SO for a given time period. Accordingly, the transistor N412 or N414 is activated or deactivated in accordance with the voltage level of the bit line. In other words, when the voltage level of the bit line is smaller than the voltage difference (V2−Vt), the transistor N420 is activated. As a result, the bit line is coupled to the sensing node SO. Thus, charges are shared between the bit line and the sensing node SO. Hence, the voltage level of the sensing node SO is lowered.

However, when the voltage level of the bit line is higher than the voltage difference (V2−Vt), the transistor N412 or N414 is deactivated. As a result, the bit line is not coupled to the sensing node SO. Thus, the voltage level of the sensing node SO is maintained.

Accordingly, the voltage level of the sensing node SO depends on the voltage level of the bit line. Since the voltage level of the sensing node SO is maintained at a high level when a corresponding cell is programmed, the transistor N448 of the register 440 is activated.

However, since the threshold voltage of the under program cell or the threshold voltage of the program prohibition cell is smaller than the verifying reference voltage Vver, the voltage level of the sensing node SO is at a low level. As a result, the N-MOS transistor N448 of the register 440 remains deactivated.

Since the second read signal READA at a high level is provided to the N-MOS transistor N444 of the register 440, data at a high level is stored in the first node QA when a corresponding cell is programmed.

However, since the threshold voltage of the under program cell is smaller than the verifying reference voltage Vver, the data stored in the T4 interval is maintained at a low level.

In the program prohibition cell, the data stored in the T4 interval is maintained at a high level.

In brief, the data at a low level is stored in the first node QA in the under program cell. However, the data at a high level is stored in the first node QA for the cell programmed normally or the program prohibition cell.

Referring to FIG. 5, in step S540, the under program cell is detected through the embodiment described with reference to FIG. 6 or FIG. 7.

In step S550, only the under program cell is programmed.

The program operation is similar to that described in step S510.

The data ‘0’ at a low level is stored in the first node QA for the under program cell. However, the data ‘1’ at a high level is stored in the first node QA for the cell programmed normally or the program prohibition cell.

In other words, the under program cell is separated from the cell programmed normally or the program prohibition cell through the data storage state. Thus, the program operation is only performed on the under program cell separated through the above process.

In step S560, the program verifying operation is performed after the program operation is complete.

The program verifying operation is similar to that described in steps S520, S530 and S532.

When the program operation is normally finished in accordance with the program of the under program cell (i.e. when the threshold voltage of the under program cell is higher than the verifying reference voltage), the data ‘2 ’ at a high level is stored in the first node QA of the page buffer 400 coupled to a corresponding cell. When all of the data is changed to a high level, the program operation is complete.

Any reference in this specification to “one embodiment,” “an embodiment,” “example embodiment,” etc., means that a particular feature, structure, or characteristic described in connection with the embodiment is included in at least one embodiment of the invention. The appearance of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with the other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of detecting an under program cell, the method comprising:
detecting second memory cells in programmed first memory cells, wherein a threshold voltage of the second memory cell is higher than a first verifying voltage; and
detecting a third memory cell in the second memory cells, wherein a threshold voltage of the third memory cell is smaller than a second verifying voltage.

2. The method of claim 1, wherein detecting the second memory cells comprises:
applying the first verifying voltage to a word line coupled to a certain cell to be read;
precharging a bit line coupled to the cell to a high level;
measuring a program of the cell to be read in accordance with a change of a voltage level of the bit line;
sensing data stored in the cell in accordance with the voltage level of the bit line; and
storing the sensed data in a register.

3. The method of claim 2, wherein precharging the bit line comprises:
precharging a sensing node to the high level through a precharge circuit of a page buffer; and
applying a first voltage to a bit line sensing transistor of a bit line sensing circuit, thereby coupling the sensing node precharged to the high level to a given bit line.

4. The method of claim 2, wherein precharging the bit line comprises:
precharging a sensing node to the high level through a precharge circuit of a page buffer; and
applying a first voltage to a bit line selecting transistor of a bit line selecting circuit, thereby coupling the sensing node precharged to the high level to a certain bit line.

5. The method of claim 2, wherein storing the sensed data comprises:
applying a second voltage that is smaller than the first voltage to a bit line sensing transistor of a bit line sensing circuit;
determining activation of the bit line sensing transistor in accordance with a voltage level of the bit line;
discharging the sensing node precharged to the high level to a low level when the bit line sensing transistor is activated;
maintaining the precharged sensing node at the high level when the bit line sensing transistor is deactivated; and
determining a level of data stored in a given node of the register in accordance with a voltage level of the sensing node.

6. The method of claim 2, wherein storing the sensed data comprises:
applying a second voltage that is smaller than a first voltage to a bit line selecting transistor of a bit line selecting circuit;
determining activation of the bit line selecting transistor in accordance with a voltage level of the bit line;
discharging the sensing node precharged to the high level to a low level when the bit line selecting transistor is activated;
maintaining the precharged sensing node at the high level when the bit line selecting transistor is activated; and
determining a level of data stored in a given node of the register in accordance with the voltage level of the sensing node.

7. The method of claim 1, wherein detecting the third memory cell of the second memory cells comprises:
applying the second verifying voltage that is higher than the first verifying voltage to a word line coupled to a specific cell to be read;
precharging a sensing node to a high level;
measuring a program of the cell in accordance with a voltage level of the bit line;
sensing data stored in the cell in accordance with the voltage level of the bit line; and
storing the sensed data in a register.

8. The method of claim 7, wherein storing the sensed data in the register comprises:
applying a second voltage that is smaller than a first voltage to a bit line sensing transistor of a bit line sensing circuit;
determining activation of the bit line sensing transistor in accordance with the voltage level of the bit line;
discharging the sensing node precharged to the high level to a low level when the bit line sensing transistor is activated;
maintaining the precharged sensing node at the high level when the bit line sensing transistor is deactivated; and
determining a level of data stored in a given node of the register in accordance with the voltage level of the sensing node.

9. The method of claim 8, wherein the sensing node is discharged to the low level when the cell is an under program cell, and the sensing node is maintained at the high level when the cell is a program prohibition cell or is programmed to a voltage greater than the second verifying voltage.

10. The method of claim 7, wherein storing the sensed data in the register comprises:
applying a second voltage that is smaller than a first voltage to a bit line selecting transistor of a bit line selecting circuit;
determining activation of the bit line selecting transistor in accordance with the voltage level of the bit line;
discharging the sensing node precharged to the high level to a low level when the bit line selecting transistor is activated;
maintaining the precharged sensing node at the high level when the bit line selecting transistor is deactivated; and
determining a level of data stored in a certain node of the register in accordance with the voltage level of the sensing node.

11. The method of claim 10, wherein the sensing node is discharged to the low level when the cell is an under program cell, and the sensing node is maintained at the high level when the cell is a program prohibition cell or is programmed to a voltage greater than the second verifying voltage.

12. A method of programming a cell in a non-volatile memory device, the method comprising:
performing a program operation on selected memory cells;
detecting first memory cells of the programmed memory cells, wherein a threshold voltage of the first memory cell is higher than a first verifying voltage;
detecting an under program cell of the first memory cells, wherein a threshold voltage of the under program cell is smaller than a second verifying voltage; and
programming the under program cell.

13. The method of claim 12, wherein data stored in a given node of a register when the cell is the under program cell is opposed to data stored in the node of the register when the cell is not the under program cell.

14. The method of claim 12, wherein detecting the first memory cells comprises:
applying the first verifying voltage to a word line coupled to a certain cell to be read;
precharging a bit line coupled to the cell to a high level;
measuring a program of the cell in accordance with a voltage level of the bit line;
sensing data stored in the cell in accordance with the voltage level of the bit line; and
storing the sensed data in a register.

15. The method of claim 14, wherein precharging the bit line comprises:
precharging a sensing node to the high level through a precharge circuit of a page buffer; and
applying a first voltage to a bit line sensing transistor of a bit line sensing circuit, thereby coupling the sensing node precharged to the high level to a given bit line.

16. The method of claim 14, wherein precharging the bit line comprises:
precharging a sensing node to the high level through a precharge circuit of a page buffer; and
applying a first voltage to a bit line selecting transistor of a bit line selecting circuit, thereby coupling the sensing node precharged to the high level to a certain bit line.

17. The method of claim 14, wherein storing the sensed data comprises:
applying a second voltage that is smaller than the first voltage to a bit line sensing transistor of a bit line sensing circuit;
determining activation of the bit line sensing transistor in accordance with a voltage level of the bit line;
discharging the sensing node precharged to the high level to a low level when the bit line sensing transistor is activated;
maintaining the precharged sensing node at the high level when the bit line sensing transistor is deactivated; and
determining a level of data stored in a given node of the register in accordance with a voltage level of the sensing node.

18. The method of claim 14, wherein storing the sensed data comprises:
applying a second voltage that is smaller than a first voltage to a bit line selecting transistor of a bit line selecting circuit;
determining activation of the bit line selecting transistor in accordance with a voltage level of the bit line;
discharging the sensing node precharged to the high level to a low level when the bit line selecting transistor is activated;
maintaining the precharged sensing node at the high level when the bit line selecting transistor is deactivated; and
determining a level of data stored in a given node of the register in accordance with the voltage level of the sensing node.

19. The method of claim 12, wherein detecting the under program cell comprises:
applying the second verifying voltage that is higher than the first verifying voltage to a word line coupled to a specific cell to be read;
precharging a sensing node to a high level;
measuring a program of the cell in accordance with a voltage level of the bit line;
sensing data stored in the cell in accordance with the voltage level of the bit line; and
storing the sensed data in a register.

20. The method of claim 19, wherein storing the sensed data in the register comprises:
applying a second voltage that is smaller than a first voltage to a bit line sensing transistor of a bit line sensing circuit;
determining activation of the bit line sensing transistor in accordance with the voltage level of the bit line;
discharging the sensing node precharged to the high level to a low level when the bit line sensing transistor is activated;
maintaining the precharged sensing node at the high level when the bit line sensing transistor is deactivated; and
determining a level of data stored in a given node of the register in accordance with the voltage level of the sensing node.

21. The method of claim 20, wherein the sensing node is discharged to the low level when the cell is an under program cell, and the sensing node is maintained at the high level when the cell is a program prohibition cell or is programmed to a voltage greater than the second verifying voltage.

22. The method of claim 19, wherein storing the sensed data in the register comprises:
applying a second voltage that is smaller than a first voltage to a bit line selecting transistor of a bit line selecting circuit;
determining activation of the bit line selecting transistor in accordance with the voltage level of the bit line;
discharging the sensing node precharged to the high level to a low level when the bit line selecting transistor is activated;
maintaining the precharged sensing node at the high level when the bit line selecting transistor is deactivated; and
determining a level of data stored in a certain node of the register in accordance with the voltage level of the sensing node.

23. The method of claim 22, wherein the sensing node is discharged to the low level when the cell is an under program cell, and the sensing node is maintained at the high level when the cell is a program prohibition cell or is programmed to a voltage greater than the second verifying voltage.
